(19) United States
(12) Patent Application Publication
(10) Pub. No.: US 2008/0206981 A1
(43) Pub. Date: Aug. 28, 2008

(54) Semiconductor device and manufacturing method therefor

(76) Inventor: Koji Tamura, Fukuyama-shi (JP)

Correspondence Address: HARNESS, DICKEY & PIERCE, P.L.C., P.O. BOX 8910, RESTON, VA, 20195, US

(21) Appl. No.: 12/081,286

(22) Filed: Apr. 14, 2008

Related U.S. Application Data
(62) Division of application No. 11/446,293, filed on Jun. 5, 2006.

(30) Foreign Application Priority Data
Jun. 6, 2005 (JP) 2005-165525

(51) Int. Cl. H01L 21/4763

(52) U.S. Cl. 438/624; 257/E21.495

(57) ABSTRACT

In a manufacturing method for a semiconductor storage device, an interlayer insulating film, a first hard mask made of an insulative material for coating the interlayer insulating film and a second hard mask are formed on a substrate. The second hard mask is opened, and with use of the second hard mask as a mask, a recess groove, where an embedded interconnection is to be embedded, is formed in the interlayer insulating film. A diffusion preventing film is formed for preventing an embedded interconnection material from diffusing into the interlayer insulating film. The second hard mask and the diffusion preventing film are made of an identical material, which is a conductive material containing a metallic element in its composition. A conductive metal to be a material of the embedded interconnection is deposited. The surface side of the conductive metal is polished to the level that the first hard mask is exposed therefrom.

### CROSS-REFERENCE TO RELATED APPLICATIONS

This Nonprovisional application claims priority under 35 U.S.C. §119(a) on Patent Application No. 2005-165525 filed in Japan on Jun. 6, 2005, the entire contents of which are hereby incorporated by reference.

### BACKGROUND OF THE INVENTION

The present invention relates to a semiconductor device and a manufacturing method therefor. More specifically, the present invention relates to a manufacturing method for a semiconductor device having an interlayer insulating film with an embedded interconnection structure (damascene structure). The present invention also relates to a semiconductor device manufactured by such a manufacturing method.

Known as a manufacturing method for this kind of semiconductor device is a dual damascene technology involving the processes of forming an interlayer insulating film on a lower interconnection, forming an interconnection groove in which an upper interconnection is to be embedded and a via hole for connecting upper and lower interconnections on the interlayer insulating film, and embedding an identical metal film in the interconnection groove and the via hole to integrate the upper interconnection and the via.

While resist masks made of organic materials have generally been used for forming such embedded interconnection patterns, hard masks made of inorganic materials have recently started to be used. For example, JP 2003-179136 A has proposed a method in which an interlayer insulating film is formed on a lower interconnection and then three mask layers are laminated as hard masks in order to form an interconnection groove in which an upper interconnection is to be embedded and a via hole on the interlayer insulating film. The three mask layers are composed of a first mask thin film made of silicon oxide or silicon carbide, a second mask thin film made of silicon nitride and a third mask thin film made of refractory metals such as titan, tantalum and tungsten, or metal alloys of titan nitride, tantalum nitride and tungsten nitride. The three mask layers, which are hard masks made of inorganic materials with high etching resistance, can increase processing accuracy of the interconnection groove and the via hole compared to the resist masks made of organic materials. In this document, after the interconnection groove and the via hole are formed, a thick copper layer is deposited thereon by electrolytic plating. Then, the thick copper layer, the third mask thin film, the second mask thin film and the first mask thin film are continuously polished by chemical mechanical polishing (CMP) to the level that the first mask thin film is exposed. Thus, the upper interconnection (embedded interconnection) and the via are formed integrally.

However, in the CMP method, the polishing rate of silicon nitride, which is generally a material of the second mask thin film, is quite lower than the polishing rate of copper which is a material of the upper interconnection, as well as the polishing rates of the materials of the third mask thin film (refractory metals such as titan, tantalum and tungsten, or metal alloys of titan nitride, tantalum nitride and tungsten nitride) and materials of the first mask thin film (silicon oxide or silicon carbide). Consequently, when the second mask thin film is polished in the regions corresponding to both sides of the interconnection groove in this manufacturing method, regions with low polishing rates and high polishing rates are generated inside the surface subject to polishing, and this makes it difficult to maintain the flatness of the polished surface and causes the problem of insufficient processed shapes. Moreover, a formation process of the second mask thin film made of silicon nitride is necessary, which causes the problem of a large number of steps and high costs.

### SUMMARY OF THE INVENTION

An object of the present invention is to provide a manufacturing method for a semiconductor device capable of maintaining flatness of a polished face in the case of embedding interconnections on the surface of an interlayer insulating film and therefore ensuring a sufficiently processed shape of the embedded interconnection structure, and to provide a manufacturing method for a semiconductor device capable of decreasing the number of manufacturing steps for cost reduction.

Another object of the present invention is to provide a semiconductor device manufactured by such a manufacturing method.

In order to accomplish the objects, a manufacturing method for a semiconductor device of the present invention comprises the steps of:

forming at least an interlayer insulating film in a specified region of which an embedded interconnection is to be embedded, a first hard mask made of an insulative material for coating the interlayer insulating film, and a second hard mask made of a material selectively etchable with respect to the first hard mask, on a substrate in this order;

opening a portion of the second hard mask corresponding to the specified region by photolithography and etching;

removing a portion of the first hard mask and the interlayer insulating film corresponding to the specified region by etching from a surface side in depth direction with use of the second hard mask as a mask so as to form a recess groove in the interlayer insulating film, where the embedded interconnection is to be embedded;

forming a diffusion preventing film along a surface of the second hard mask present in an inner wall of the recess groove and on both sides of the recess groove for preventing an embedded interconnection material from diffusing into the interlayer insulating film,

the second hard mask and the diffusion preventing film being made of an identical material which is a conductive material containing a metallic element in its composition;

depositing a conductive metal, which is to be a material of the embedded interconnection, on the substrate so as to fill in the recess groove covered with the diffusion preventing film; and

polishing a surface side of the conductive metal to a level that the first hard mask is exposed therefrom so as to leave the conductive metal in the recess groove as the embedded interconnection.

In the step of polishing the surface side of the conductive metal to the level that the first hard mask is exposed therefrom in the manufacturing method for a semiconductor device, first, the conductive metal is polished both in the region on the recess groove and in the region corresponding to both sides of the recess groove. Next, while the conductive metal is polished in the region on the recess groove, the diffusion preventing film and the second hard mask are polished in sequence in the region corresponding to both sides of the recess groove. Herein, the diffusion preventing film and the second hard mask are made of the identical material, which is a conductive material containing a metallic element in its composition. Therefore, it becomes possible to bring the polishing rate of the diffusion preventing film and the second hard mask close to the polishing rate of the conductive metal compared to the polishing rate of silicon nitride (conventional example). Consequently, in the step of polishing the surface side of the conductive metal to the level that the first hard mask is exposed therefrom, the flatness of the polished face can be maintained compared to the conventional example. This makes it possible to ensure a sufficiently processed shape of the embedded interconnection structure. Moreover, since the diffusion preventing film and the second hard mask are made of an identical conductive material containing a metallic element in its composition, the step of forming a hard mask made of silicon nitride can be decreased and thereby cost reduction is implemented.

In the manufacturing method for a semiconductor device of one embodiment,

the material of the second hard mask and the material of the diffusion preventing film are made only of the metallic element, and the metallic element is any one of tantalum, tungsten and zirconium, and

the conductive metal is copper.

According to the manufacturing method for a semiconductor device of this embodiment, the material of the second hard mask and the material of the diffusion preventing film are made of any one of tantalum (Ta), tungsten (W) and zirconium (Zr), and the conductive metal is copper. Therefore, it becomes possible to bring the polishing rate of the diffusion preventing film and the second hard mask close to the polishing rate of the conductive metal. Consequently, in the step of polishing the surface side of the conductive metal to the level that the first hard mask is exposed therefrom, the flatness of the polished face can be maintained more sufficiently. This makes it possible to ensure a more sufficiently processed shape of the embedded interconnection structure.

In the manufacturing method for a semiconductor device of one embodiment,

the material of the second hard mask and the material of the diffusion preventing film are a metallic compound having an identical composition, and

after the recess groove is formed and before the diffusion preventing film is formed, a foundation film made of a metallic element identical to the metallic element contained in the composition of the second hard mask and the diffusion preventing film is formed along the surface of the second hard mask present in the inner wall of the recess groove and on both sides of the recess groove.

In the manufacturing method for a semiconductor device of this embodiment, the material of the diffusion preventing film is a metallic compound, and therefore the freedom of material selection is increased compared to the case where the material of the diffusion preventing film is made only of the metallic element. As a result, it becomes possible to select a material which can effectively prevent the embedded interconnection material from diffusing into the interlayer insulating film as the material of the diffusion preventing film, and it also becomes possible to select a material which can effectively enhance adhesion between the diffusion preventing film and the conductive metal as the material of the foundation film.

Moreover, the foundation film is made of a metallic element identical to the metallic element contained in the composition of the second hard mask and the diffusion preventing film. Therefore, it becomes possible to bring the polishing rate of the foundation film close to the polishing rate of the conductive metal, as well as the polishing rate of the diffusion preventing film and the second hard mask, compared to the polishing rate of silicon nitride. Consequently, in the step of polishing the surface side of the conductive metal to the level that the first hard mask is exposed therefrom, the flatness of the polished face can be maintained. This makes it possible to ensure a sufficiently processed shape of the embedded interconnection structure.

In the manufacturing method for a semiconductor device of one embodiment,

the metallic compound, which is the material of the second hard mask and the diffusion preventing film, is any one of tantalum nitride, tungsten nitride and zirconium nitride, and

the conductive metal is copper.

Herein, in the cases where the metallic compound is tantalum nitride, tungsten nitride and zirconium nitride, the material of the foundation film is accordingly to be tantalum (Ta), tungsten (W) and zirconium (Zr).

In the manufacturing method for a semiconductor device of this embodiment, it becomes possible to bring the polishing rate of the diffusion preventing film, the foundation film and the second hard mask close to the polishing rate of the conductive metal. Consequently, in the step of polishing the surface side of the conductive metal to the level that the first hard mask is exposed therefrom, the flatness of the polished face can be maintained more sufficiently. This makes it possible to ensure a more sufficiently processed shape of the embedded interconnection structure.

Moreover, the material of the diffusion preventing film can effectively prevent the embedded interconnection material from diffusing into the interlayer insulating film, and the material of the foundation film can effectively enhance adhesion between the diffusion preventing film and the conductive metal.

Moreover, in the manufacturing method for a semiconductor device of one embodiment, the material of the first hard mask is any one of silicon dioxide, silicon carbide, silicon oxynitride and silicon carbonitride.

According to the manufacturing method for a semiconductor device of this embodiment, in the step of polishing the surface side of the conductive metal to the level that the first hard mask is exposed therefrom, the surface of interlayer insulating film can effectively be coated with the first hard mask.

The manufacturing method for a semiconductor device of one embodiment further comprises the step of:

forming a lower interconnection traveling through a region corresponding to the specified region, and a lower etching stopper film which is made of a material selectively etchable with respect to the interlayer insulating film and which is in contact with an upper face of the lower interconnection, on the substrate in this order before the step of forming the interlayer insulating film,

wherein, following the forming of the recess groove, the lower etching stopper film exposed in a bottom of the recess groove is removed by etching.

In the manufacturing method for a semiconductor device of this embodiment, following the forming of the recess groove, the lower etching stopper film exposed in the bottom of the recess groove is removed by etching. This makes the upper face of the lower interconnection exposed. Therefore, after the step of depositing the conductive metal, the lower interconnection and the embedded interconnection can be connected through the diffusion preventing film.

The manufacturing method for a semiconductor device of one embodiment, further comprises the steps of:

forming a lower interlayer insulating film and an etching stopper film on the substrate in this order before the step of forming the interlayer insulating film; and

forming a via hole extending in depth direction through a portion of the first hard mask, the interlayer insulating film, the etching stopper film and the lower interlayer insulating film corresponding to a portion of the specified region by photolithography and etching after the step of exposing a portion of the first hard mask corresponding to the specified region and before the step of forming the recess groove for the embedded interconnection to be embedded therein,

wherein, following the forming of the recess groove, the etching stopper film exposed in a bottom of the recess groove is removed by etching,

wherein in the step of forming the diffusion preventing film, the diffusion preventing film goes along an inner wall of the via hole in addition to an inside of the recess groove, and

wherein in the step of depositing the conductive metal which is to be the material of the embedded interconnection, the conductive metal which is to be the material of the embedded interconnection fills in the recess groove and the via hole which are covered with the diffusion preventing film.

In the manufacturing method for a semiconductor device of this embodiment, in the step of depositing the conductive metal which is to be the material of the embedded interconnection, the conductive metal which is to be the material of the embedded interconnection fills in the recess groove and the via hole which are covered with the diffusion preventing film. Therefore, it becomes possible to embed an identical metal film in the recess groove and the via hole so that the embedded interconnection and the via can be formed integrally (dual damascene technology).

In the manufacturing method for a semiconductor device of one embodiment, further comprises the step of:

forming a lower interconnection traveling through a region corresponding to the specified region, and a lower etching stopper film which is made of a material selectively etchable with respect to the interlayer insulating film and which is in contact with an upper face of the lower interconnection, on the substrate in this order before the step of forming the interlayer insulating film,

wherein, following the forming of the via hole, the lower etching stopper film exposed in a bottom of the via hole is removed by etching.

In the manufacturing method for a semiconductor device of this embodiment, following the forming of the via hole, the lower etching stopper film exposed in a bottom of the via hole is removed by etching. This makes the upper face of the lower interconnection exposed. Therefore, after the step of depositing the conductive metal, the lower interconnection and the embedded interconnection can be connected through the diffusion preventing film.

A semiconductor device of the present invention comprises:

a lower interconnection traveling through a specified region on a substrate;

an interlayer insulating film formed on the lower interconnection at a level that the interlayer insulating film is substantially in contact with an upper face of the lower interconnection;

a recess groove which is formed in a region of the interlayer insulating film corresponding to a region on the lower interconnection and which has a depth extending from a surface side to the upper face of the lower interconnection;

a first thin film which is formed on a surface of the interlayer insulating film corresponding to both sides of the recess groove and which is made of an insulative material for coating the interlayer insulating film;

an embedded interconnection which has an upper face at a level substantially identical to a surface of the first thin film and which is made of a conductive metal embedded in the recess groove; and

a diffusion preventing film which is provided between a conductive metal constituting the embedded interconnection and an inner wall of the recess groove along the inner wall and which is made of a material for preventing the conductive metal from diffusing into the interlayer insulating film, each of which is formed on the substrate,

wherein the diffusion preventing film is a metal film made of any one of tantalum, tungsten and zirconium.

In another aspect, a semiconductor device of the present invention comprises:

a lower interconnection traveling through a specified region on a substrate;

an interlayer insulating film formed on the lower interconnection at a level that the interlayer insulating film is substantially in contact with an upper face of the lower interconnection;

a recess groove which is formed in a region of the interlayer insulating film corresponding to a region on the lower interconnection and which has a depth extending from a surface side to the upper face of the lower interconnection;

a first thin film which is formed on a surface of the interlayer insulating film corresponding to both sides of the recess groove and which is made of an insulative material for coating the interlayer insulating film;

an embedded interconnection which has an upper face at a level substantially identical to a surface of the first thin film and which is made of a conductive metal embedded in the recess groove; and

a diffusion preventing film which is provided between a conductive metal constituting the embedded interconnection and an inner wall of the recess groove along the inner wall and which is made of a material for preventing the conductive metal from diffusing into the interlayer insulating film, each of which is formed on the substrate,

wherein the diffusion preventing film is composed of two layers: a foundation film which is made of any one of tantalum, tungsten and zirconium and which is in contact with the inner wall of the recess groove; and a metallic compound which is made of nitride of a metallic element identical to the metallic element constituting the foundation film and which is in contact with the conductive metal constituting the embedded interconnection.

Herein, in the cases where the material of the foundation film is tantalum, tungsten and zirconium, the metallic compound is accordingly to be tantalum nitride, tungsten nitride and zirconium nitride.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIGS. 1A to 1H are cross sectional views each of which shows a step in a manufacturing method for a semiconductor device in a first embodiment of the present invention;

FIGS. 2A to 2F are cross sectional views each of which shows a step in a manufacturing method for a semiconductor device in a second embodiment of the present invention;

### DETAILED DESCRIPTION OF THE INVENTION

The present invention will be described hereinbelow in detail with conjunction to the embodiments with reference to the drawings.

### First Embodiment

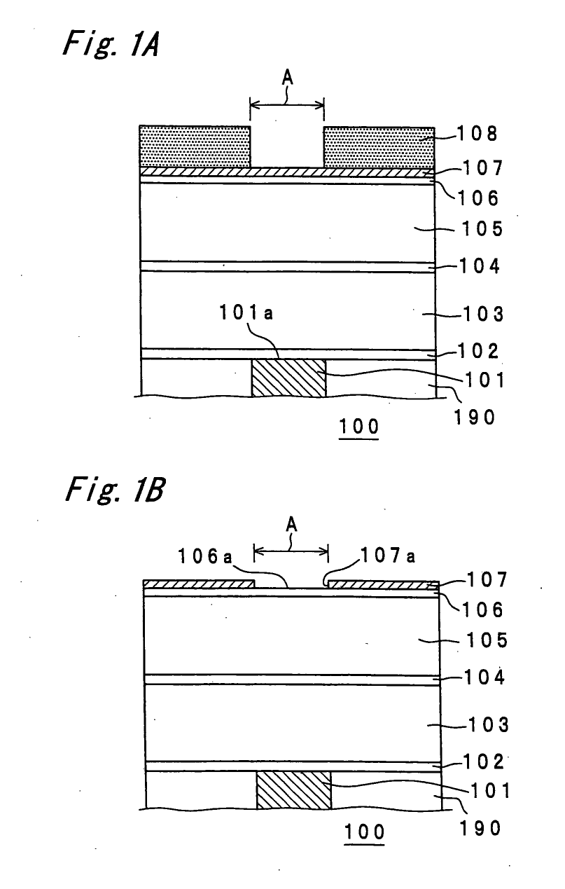

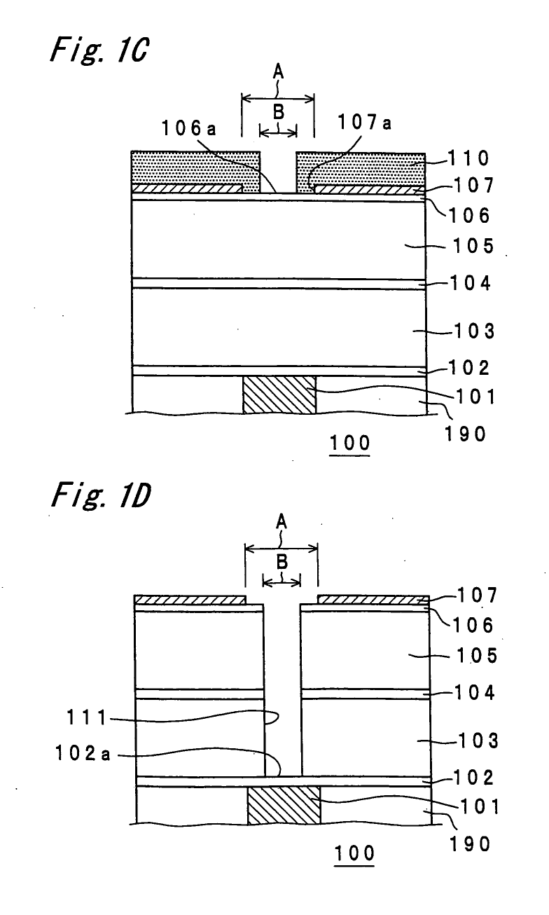

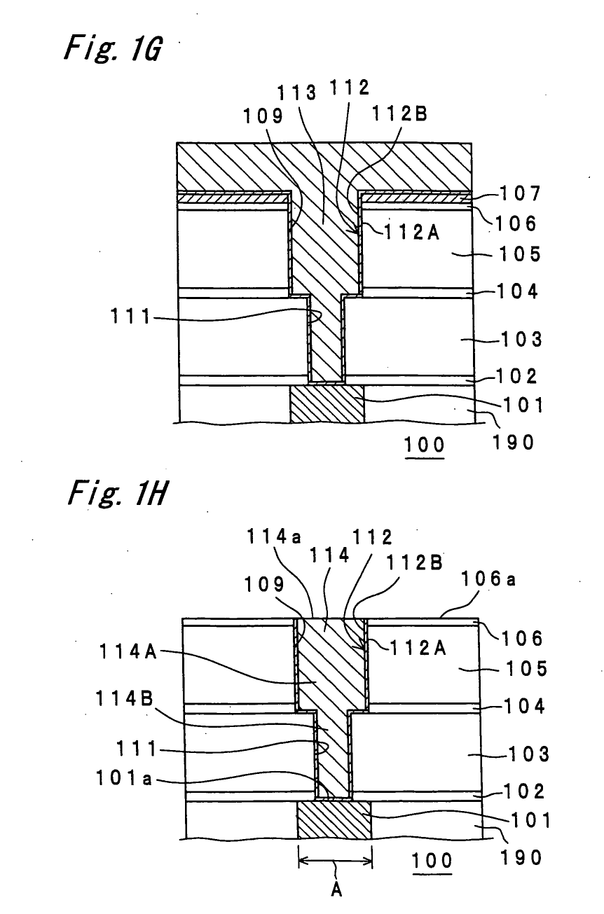

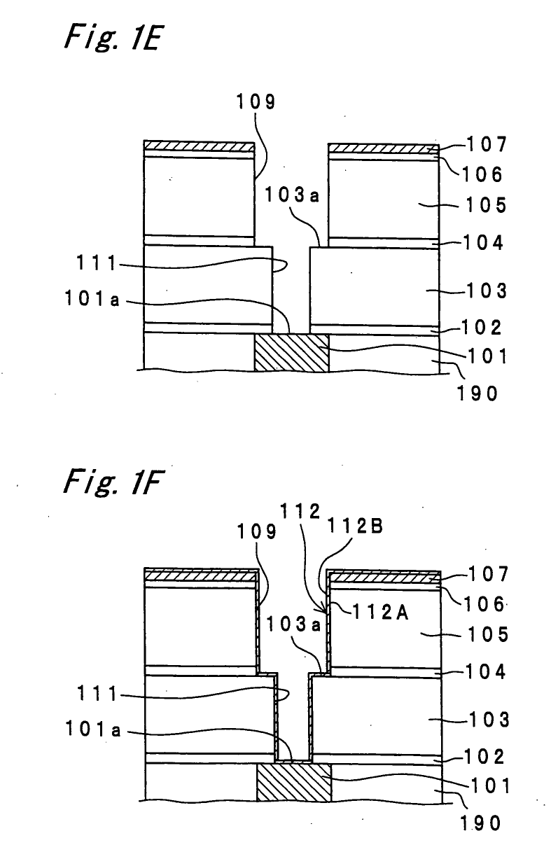

FIGS. 1A to 1H are cross sectional views showing the steps in a manufacturing method for a semiconductor device in a first embodiment of the present invention.

As shown in FIG. 1A, an insulating layer 190 is formed in advance on a semiconductor substrate 100, and a lower interconnection 101 is embedded in a portion of the insulating layer 190 corresponding to a specified region A. The width of the lower interconnection 101 is set in the range of 0.05 μm to 200 μm, and an upper face 101a of the lower interconnection 101 and the surface of the insulating layer 190 existing on both sides of the lower interconnection 101 are planar. In the present embodiment, a cap film 102 with a thickness of 10 nm to 50 nm, a first insulating film 103 with a thickness of 100 nm to 500 nm, an etching stopper film 104 with a thickness of 10 nm to 50 nm, and a second insulating film 105 with a thickness of 100 nm to 500 nm are formed in this order on the insulating layer 190 and the lower interconnection 101. Further, on top of these films, a first hard mask 106 with a thickness of 10 nm to 100 nm and a second hard mask 107 with a thickness of 10 nm to 50 nm are formed in this order. Further, a groove pattern resist 108 is formed on the second hard mask 107 by photolithography.

Herein, the cap film 102, which serves as a lower etching stopper film for stopping the etching process in the later-described step of forming a via hole, may be made of a material such as SiN, SiC, SiON and SiCN. The first insulating film 103, which is a lower interlayer insulating film where the via hole is to be formed, may be made of a material such as silicon oxide and low-k dielectric films. Examples of the low-k dielectric films which can be used include inorganic insulating films such as SiOF, SiOC and porous silica films, and organic insulating films such as polyimide films and fluorine-doped amorphous carbon films. The etching stopper film 104, which serves to stop the etching process in the later-described step of forming a recess groove, may be made of a material such as SiN, SiC, SiON and SiCN. The second insulating film 105, which is an interlayer insulating film where the recess groove is to be formed, may be made of a material such as silicon oxide and low-k dielectric films as well as the first insulating film 103. As described later, in the case of simultaneously etching the second insulating film 105 and the first insulating film 103, the material of the second insulating film 105 should preferably be identical to the material of the first insulating film 103.

The first hard mask 106 serves to stop the etching process in the later-described step of pattern-processing (opening) the second hard mask 107 by etching. The first hard mask 106 may be made of a material selectively etchable with respect to the material of the second hard mask 107 as described next, such as SiO₂, SiN, SiC, SiON and SiCN. Moreover, the first hard mask 106 serves to protect the second insulating film 105 from polishing agents in a later-described chemical mechanical polishing (CMP) step. The first hard mask 106 may be made of a material identical to the material of the etching stopper film 104.

The second hard mask 107 is used as a hard mask for obtaining high etching resistance in the later-described step of forming a recess groove in the second insulating film 105 by etching. The second hard mask 107 is made of a material selectively etchable with respect to the first hard mask 106 (i.e., a material different from the material of the first hard mask 106) and identical to a conductive material constituting a later-described diffusion preventing film 112. In this example, the second hard mask 107 is made of any one of tantalum nitride, tungsten nitride and zirconium nitride and is formed by sputtering or reactive sputtering.

The groove pattern resist 108 is formed, by known general forming methods, to have an opening which defines a region A in which the embedded interconnection is to be provided. For example, the groove pattern resist 108 is formed by applying a photoresist composition and then exposing the photoresist composition with optimum exposure amount and focus with use of an ArF excimer laser scanner so as to develop a resultant image. Examples of the photoresist composition which can be used include a chemically-amplified positive-acting resist composition containing a general base resin and an acid generating agent.

Next, as shown in FIG. 1B, dry etching is performed with the groove pattern resist 108 as a mask and with use of an etching gas such as CₓF_{y}, CₓH_{y}F_{z}, Cl₂, BCl₃ and Ar so as to selectively remove a portion of the second hard mask 107 corresponding to the region A from the first hard mask 106. Consequently, an opening 107a is formed in a portion of the second hard mask 107 corresponding to the region A, and a surface 106a of the first hard mask 106 is exposed through the opening 107a. Then, the groove pattern resist 108 is removed by plasma ashing with use of an ashing gas such as oxygen.

Next, as shown in FIG. 1C, photolithography is performed to form a via pattern resist 110 on the second hard mask 107 and the first hard mask 106. The via pattern resist 110 is formed, by known general forming methods as well as the groove pattern resist 108, to have an opening which defines a region B in which a via hole is to be provided. The diameter of the region B, i.e., the diameter of the via hole is set in the range of 0.05 μm to 20 μm.

Next, as shown in FIG. 1D, dry etching is performed with the via pattern resist 110 as a mask and with use of an etching gas such as CₓF_{y}, CₓH_{y}F_{z}, O₂, N₂ and Ar so as to form a via hole 111 extending through a portion of the first hard mask 106, the second insulating film 105, the etching stopper film 104 and the first insulating film 103 corresponding to the region B in depth direction from the surface side to a surface 102a of the cap film 102. Then, the via pattern resist 110 is removed by plasma ashing with use of an ashing gas such as oxygen.

Next, as shown in FIG. 1E, dry etching is performed with the second hard mask 107 and the first hard mask 106 as masks and with use of an etching gas such as CₓF_{y}, CₓH_{y}F_{z}, O₂, N₂ and Ar so that a portion of the first hard mask 106 and the second insulating film 105 corresponding to the region A is etched in depth direction from the surface side to the surface of the etching stopper film 104 in order to form a recess groove 109 in the second insulating film 105 where an embedded interconnection is to be embedded. Then, the etching stopper film 104 exposed in the bottom of the recess groove 109 and the cap film 102 exposed in the bottom of the via hole 111 are removed by selective dry etching from the second insulating film 105 and the first insulating film 103, respectively. As a result, the upper face 101a of the lower interconnection 101 is exposed in the bottom of the via hole 111 and a surface 103a of the first insulating film 103 is exposed in the bottom of the recess groove 109.

In the case where the recess groove 109 is formed in this way, generation of edge roughness over the entire inner wall of the formed recess groove 109 can be reduced due to the etching process with the second hard mask 107 and the first hard mask 106 as masks even when the recess groove 109 is of a microscopic pattern.

Next, as shown in FIG. 1F, a foundation film 112A made of a metallic element identical to the metallic element contained in the composition of the second hard mask 107 and a diffusion preventing film 112B made of a material identical to the material of the second hard mask 107 are formed inside the recess groove 109, inside the via hole 111 and along the surface of the second hard mask 107 existing on both sides of the recess groove 109 by sputtering or evaporation. Herein, in the cases where the material of the second hard mask 107 is tantalum nitride, tungsten nitride and zirconium nitride, the material of the foundation film 112A is accordingly to be Ta, W and Zr.

The diffusion preventing film 112B has a function of preventing the material of a later-described embedded interconnection (copper) from diffusing into the second insulating film 105 and the first insulating film 103. While the foundation film 112A mainly serves to enhance adhesion between the material of the embedded interconnection (copper) and the diffusion preventing film 112B, it also has a function, to some degree, of preventing the material of the embedded interconnection (copper) from diffusing into the second insulating film 105 and the first insulating film 103. Therefore, in the broad sense, the foundation film 112A combined with the diffusion preventing film 112B may be referred to as a diffusion preventing film 112. In this example, the thickness of the entire diffusion preventing film 112 is about 1 nm to 40 nm, in which the thickness of the foundation film 112A is 0.5 nm to 20 nm.

Next, as shown in FIG. 1G, a conductive metal 113 with a thickness of about 500 nm to 1000 nm is deposited on the substrate 100 by sputtering and plating so that the recess groove 109 and the via hole 111 covered with the diffusion preventing film 112 are filled in. In this example, the conductive metal is copper.

Next, as shown in FIG. 1H, the surface side of the conductive metal 113 is polished by CMP method to the level that the first hard mask 106 is exposed therefrom in order to planarize the surface. It is to be noted that in FIG. 1H, the polished conductive metal is denoted by reference numeral 114.

Thus, by embedding the same conductive metal 114 in the recess groove 109 and the via hole 111, an upper interconnection 114A and a via 114B are formed integrally (dual damascene technology).

In the above-described polishing step, first, the conductive metal 113 is polished both in the region A on the recess groove 109 and in the region corresponding to both sides of the recess groove 109. Next, while the conductive metal 113 is polished in the region A on the recess groove 109, the diffusion preventing film 112B, the foundation film 112A and the second hard mask 107 are polished in sequence in the region corresponding to both sides of the recess groove 109. Herein, the diffusion preventing film 112B and the second hard mask 107 are made of the identical material, which is any one of tantalum nitride, tungsten nitride and zirconium nitride. Moreover, in the cases where the materials of the diffusion preventing film 112B and the second hard mask 107 are respectively tantalum nitride, tungsten nitride and zirconium nitride, the material of the foundation film 112A is accordingly to be Ta, W and Zr. Therefore, it becomes possible to bring the polishing rate of the diffusion preventing film 112B, the foundation film 112A and the second hard mask 107 close to the polishing rate of the conductive metal 113 compared to the polishing rate of silicon nitride (conventional example). Consequently, in the step of polishing the surface side of the conductive metal 113 to the level that the first hard mask is exposed therefrom, the flatness of polished faces 114a, 106a can be maintained compared to the conventional example. This makes it possible to ensure a sufficiently processed shape of the embedded interconnection structure. As a result, leak current between embedded interconnections can be reduced, and performance, yields and reliability of the semiconductor device can be enhanced.

Moreover, since the diffusion preventing film 112B, the foundation film 112A and the second hard mask 107 are made of an identical material, the step of forming a hard mask made of silicon nitride stated in the conventional example can be decreased and thereby cost reduction is implemented.

Although description has been given of the case where the etching stopper film 104 is present between the first insulating film 103 and the second insulating film 105 in the first embodiment, the present invention is not limited to the case. It is possible to form both the recess groove 109 and the via hole 111 in an interlayer insulating film not including the etching stopper film 104. In this case, an effect similar to that in the first embodiment can be obtained.

### Second Embodiment

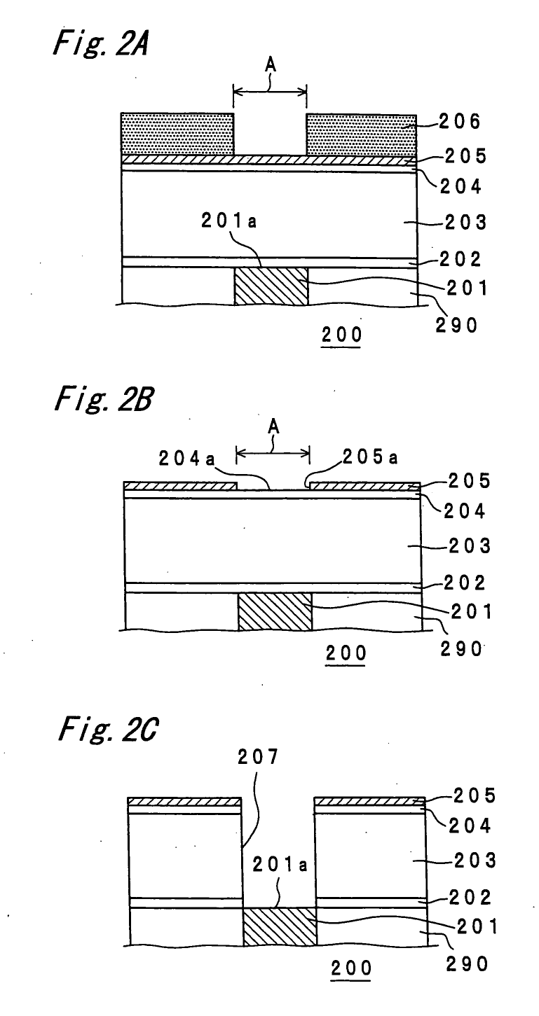

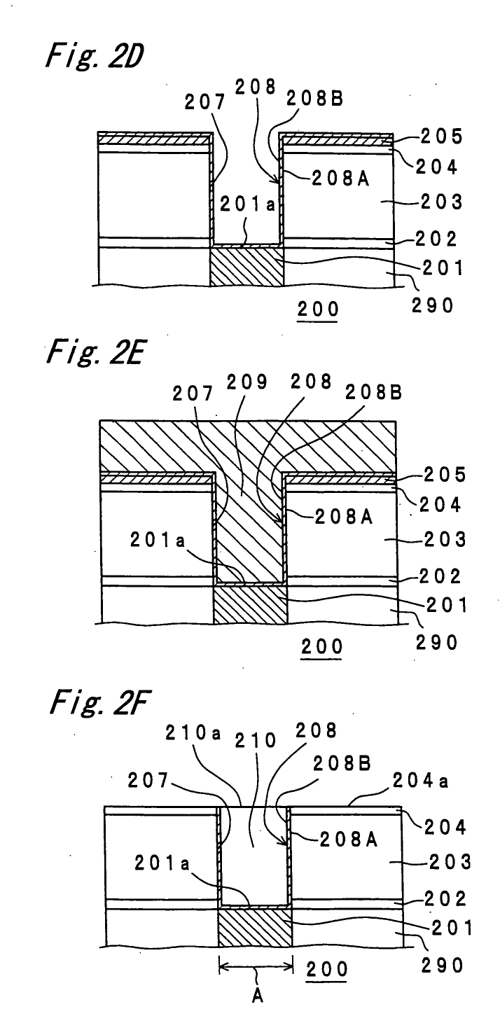

FIGS. 2A to 2F are cross sectional views showing the steps by a manufacturing method for a semiconductor device in a second embodiment of the present invention.

As shown in FIG. 2A, an insulating layer 290 is formed in advance on a semiconductor substrate 200, and a lower interconnection 201 is embedded in a portion of the insulating layer 290 corresponding to a specified region A. The width of the lower interconnection 201 is set in the range of 0.05 μm to 20.0 μm, and an upper face 201a of the lower interconnection 201 and the surface of the insulating layer 290 existing on both sides of the lower interconnection 201 are planar. In the present embodiment, a cap film 202 with a thickness of 10 nm to 50 nm and a first insulating film 203 with a thickness of 100 nm to 500 nm are formed in this order on the lower interconnection 201 and the insulating layer 290. Further, on top of these films, a first hard mask 204 with a thickness of 10 nm to 100 nm and a second hard mask 205 with a thickness of 10 nm to 50 nm are formed in this order. Further, a groove pattern resist 206 is formed on the second hard mask 205 by photolithography.

Herein, the cap film 202, which serves as an etching stopper film for stopping the etching process in the later-described step of forming a recess groove, may be made of a material such as SiN, SiC, SiON and SiCN. The first insulating film 103, which is an interlayer insulating film where the recess groove is to be formed, may be made of a material such as silicon oxide and low-k dielectric films. Examples of the low-k dielectric films which can be used include inorganic insulating films such as SiOF, SiOC and porous silica films, and organic insulating films such as polyimide films and fluorine-doped amorphous carbon films.

The first hard mask 204 serves to stop the etching process in the later-described step of pattern-processing (opening) the second hard mask 205 by etching. The first hard mask 204 may be made of a material selectively etchable with respect to the material of the second hard mask 205 as described next, such as SiO₂, SiN, SiC, SiON and SiCN. Moreover, the first hard mask 204 serves to protect the first insulating film 203 from polishing agents in a later-described chemical mechanical polishing (CMP) step.

The second hard mask 205 is used as a hard mask for obtaining high etching resistance in the later-described step of forming a recess groove in the first insulating film 203 by etching. The second hard mask 205 is made of a material selectively etchable with respect to the first hard mask 204 (i.e., a material different from the material of the first hard mask 204) and identical to a conductive material constituting a later-described diffusion preventing film 208. In this example, the second hard mask 205 is made of any one of tantalum nitride, tungsten nitride and zirconium nitride and is formed by sputtering or reactive sputtering.

The groove pattern resist 206 is formed, by known general forming methods, to have an opening which defines a region A in which the embedded interconnection is to be provided. For example, the groove pattern resist 206 is formed by applying a photoresist composition and then exposing the photoresist composition with optimum exposure amount and focus with use of an ArF excimer laser scanner so as to develop a resultant image. Examples of the photoresist composition which can be used include a chemically-amplified positive-acting resist composition containing a general base resin and an acid generating agent.

Next, as shown in FIG. 2B, dry etching is performed with the groove pattern resist 206 as a mask and with use of an etching gas such as CₓF_{y}, CₓH_{y}F_{z}, Cl₂, BCl₃ and Ar so as to selectively remove a portion of the second hard mask 205 corresponding to the region A from the first hard mask 204. Consequently, an opening 205a is formed in a portion of the second hard mask 205 corresponding to the region A, and a surface 204a of the first hard mask 204 is exposed through the opening 205a. Then, the groove pattern resist 206 is removed by plasma ashing with use of an ashing gas such as oxygen.

Next, as shown in FIG. 2C, dry etching is performed with the second hard mask 205 as a mask and with use of an etching gas such as CₓF_{y}, CₓH_{y}F_{z}, O₂, N₂ and Ar so that a portion of the first hard mask 204 and the second insulating film 203 corresponding to the region A is etched in depth direction from the surface side to the surface of the cap film 202 in order to form a recess groove 207 in the first insulating film 203 where an embedded interconnection is to be embedded. Then, the cap film 202 exposed in the bottom of the recess groove 207 is removed by selective dry etching from the first insulating film 203. As a result, a surface 201a of the lower interconnection 201 is exposed in the bottom of the recess groove 207.

Next, as shown in FIG. 2D, a foundation film 208A made of a metallic element identical to the metallic element contained in the composition of the second hard mask 205 and a diffusion preventing film 208B made of a material identical to the material of the second hard mask 205 are formed inside the recess groove 207 and along the surface of the second hard mask 205 existing on both sides of the recess groove 207 by sputtering or evaporation. Herein, in the cases where the material of the second hard mask 205 is tantalum nitride, tungsten nitride and zirconium nitride, the material of the foundation film 208A is accordingly to be Ta, W and Zr.

The diffusion preventing film 208B has a function of preventing the material of a later-described embedded interconnection (copper) from diffusing into the first insulating film 203. While the foundation film 208A mainly serves to enhance adhesion between the material of the embedded interconnection (copper) and the diffusion preventing film 208B, it also has a function, to some degree, of preventing the material of the embedded interconnection (copper) from diffusing into the first insulating film 203. Therefore, in the broad sense, the foundation film 208A combined with the diffusion preventing film 208B may be referred to as a diffusion preventing film 208. In this example, the thickness of the entire diffusion preventing film 208 is about 1 nm to 20 nm, in which the thickness of the foundation film 208A is 0.5 nm to 20 nm.

Next, as shown in FIG. 2E, a conductive metal 209 with a thickness of about 500 nm to 1000 nm is deposited on the substrate 200 by sputtering and plating so that the recess groove 207 covered with the diffusion preventing film 208 is filled in. In this example, the conductive metal is copper.

Next, as shown in FIG. 2F, the surface side of the conductive metal 209 is polished by CMP method to the level that the-first hard mask 204 is exposed in order to planarize the surface. It is to be noted that in FIG. 2F, the polished conductive metal is denoted by reference numeral 210.

Thus, by embedding conductive metal 209 in the recess groove 207, an upper interconnection 210 is formed.

A manufactured semiconductor device has a following structure. That is, the semiconductor device includes a lower interconnection 201 traveling through a specified region A on a substrate 200, and an interlayer insulating film 203 formed on the lower interconnection 201 at a level that the interlayer insulating film 203 is substantially in contact with an upper face 201a of the lower interconnection. In the specified region A in the interlayer insulating film 203, a recess groove 207 having a depth extending from the surface side to the upper face 201a of the lower interconnection is formed. A first hard mask 204 as a first thin film made of an insulative material for coating the interlayer insulating film 203 is formed on the surface of the interlayer insulating film 203 corresponding to both sides of the recess groove 207. An embedded interconnection 210 made of a conductive metal is embedded in the recess groove 207. An upper face 210a of the embedded interconnection 210 is at a level substantially identical to a surface 204a of the first hard mask 204. A diffusion preventing film 208 is provided between a conductive metal constituting the embedded interconnection 210 and an inner wall of the recess groove 207 along the inner wall. The diffusion preventing film 208 is composed of two layers: a foundation film 208A which is made of any one of tantalum, tungsten and zirconium and which is in contact with the inner wall of the recess groove 207; and a metallic compound 208B which is made of nitride of a metallic element identical to the metallic element constituting the foundation film 208A and which is in contact with the conductive metal constituting the embedded interconnection 210.

In the polishing step, first, the conductive metal 209 is polished in the region A on the recess groove 207 and in the region corresponding to both sides of the recess groove 207. Next, while the conductive metal 209 is polished in the region A on the recess groove 207, the diffusion preventing film 208B, the foundation film 208A and the second hard mask 205 are polished in sequence in the region corresponding to both sides of the recess groove 207. Herein, the diffusion preventing film 208B and the second hard mask 205 are made of the identical material, which is any one of tantalum nitride, tungsten nitride and zirconium nitride. Moreover, in the cases where the materials of the diffusion preventing film 208B and the second hard mask 205 are respectively tantalum nitride, tungsten nitride and zirconium nitride, the material of the foundation film 208A is accordingly to be Ta, W and Zr. Therefore, it becomes possible to bring the polishing rate of the diffusion preventing film 208B, the foundation film 208A and the second hard mask 205 close to the polishing rate of the conductive metal 209 compared to the polishing rate of silicon nitride (conventional example). Consequently, in the step of polishing the surface side of the conductive metal 209 to the level that the first hard mask 204 is exposed therefrom, the flatness of polished faces 210a, 204a can be maintained compared to the conventional example. This makes it possible to ensure a sufficiently processed shape of the embedded interconnection structure. As a result, leak current between embedded interconnections can be reduced, and performance, yields and reliability of the semiconductor device can be enhanced.

Moreover, since the diffusion preventing film 208B, the foundation film 208A and the second hard mask 205 are made of an identical material, the step of forming a hard mask made of silicon nitride stated in the conventional example can be decreased and thereby cost reduction is implemented.

Although in each of the embodiments disclosed, the material of the diffusion preventing film 112B, 208B and the second hard mask 107, 205 is any one of tantalum nitride, tungsten nitride and zirconium nitride, the material is not limited thereto. The material of the diffusion preventing film 112B, 208B and the second hard mask 107, 205 may be any one of Ta, W and Zr. In such a case, the foundation film can be omitted, and this allows further reduction in number of the steps and implements cost reduction.

Although in the embodiments disclosed, description has been given of the cases of the single layer interconnection and the two-layer interconnection connected via a via, the present invention is not limited to these cases. The present invention is also applicable to the case of manufacturing a multilevel interconnection structure composed of three or more layers.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

1. A manufacturing method for a semiconductor device, comprising the steps of:
forming at least an interlayer insulating film in a specified region of which an embedded interconnection is to be embedded, a first hard mask made of an insulative material for coating the interlayer insulating film, and a second hard mask made of a material selectively etchable with respect to the first hard mask, on a substrate in this order;
opening a portion of the second hard mask corresponding to the specified region by photolithography and etching;
removing a portion of the first hard mask and the interlayer insulating film corresponding to the specified region by etching from a surface side in depth direction with use of the second hard mask as a mask so as to form a recess groove in the interlayer insulating film, where the embedded interconnection is to be embedded;
forming a diffusion preventing film along a surface of the second hard mask present in an inner wall of the recess groove and on both sides of the recess groove for preventing an embedded interconnection material from diffusing into the interlayer insulating film,
the second hard mask and the diffusion preventing film being made of an identical material which is a conductive material containing a metallic element in its composition;
depositing a conductive metal, which is to be a material of the embedded interconnection, on the substrate so as to fill in the recess groove covered with the diffusion preventing film; and
polishing a surface side of the conductive metal to a level that the first hard mask is exposed therefrom so as to leave the conductive metal in the recess groove as the embedded interconnection.

2. The manufacturing method for a semiconductor device according to claim 1,
wherein the material of the second hard mask and the material of the diffusion preventing film are made only of the metallic element, and the metallic element is any one of tantalum, tungsten and zirconium, and
wherein the conductive metal is copper.

3. The manufacturing method for a semiconductor device according to claim 1,
wherein the material of the second hard mask and the material of the diffusion preventing film are a metallic compound having an identical composition, and
wherein after the recess groove is formed and before the diffusion preventing film is formed, a foundation film made of a metallic element identical to the metallic element contained in the composition of the second hard mask and the diffusion preventing film is formed along the surface of the second hard mask present in the inner wall of the recess groove and on both sides of the recess groove.

4. The manufacturing method for a semiconductor device according to claim 3,
wherein the metallic compound, which is the material of the second hard mask and the diffusion preventing film, is any one of tantalum nitride, tungsten nitride and zirconium nitride, and
wherein the conductive metal is copper.

5. The manufacturing method for a semiconductor device according to claim 1,
wherein the material of the first hard mask is any one of silicon dioxide, silicon carbide, silicon oxynitride and silicon carbonitride.

6. The manufacturing method for a semiconductor device according to claim 1, further comprising the step of:
forming a lower interconnection traveling through a region corresponding to the specified region, and a lower etching stopper film which is made of a material selectively etchable with respect to the interlayer insulating film and which is in contact with an upper face of the lower interconnection, on the substrate in this order before the step of forming the interlayer insulating film,
wherein, following the forming of the recess groove, the lower etching stopper film exposed in a bottom of the recess groove is removed by etching.

7. The manufacturing method for a semiconductor device according to claim 1, further comprising the steps of:
forming a lower interlayer insulating film and an etching stopper film on the substrate in this order before the step of forming the interlayer insulating film; and
forming a via hole extending in depth direction through a portion of the first hard mask, the interlayer insulating film, the etching stopper film and the lower interlayer insulating film corresponding to a portion of the specified region by photolithography and etching after the step of exposing a portion of the first hard mask corresponding to the specified region and before the step of forming the recess groove for the embedded interconnection to be embedded therein,
wherein, following the forming of the recess groove, the etching stopper film exposed in a bottom of the recess groove is removed by etching,
wherein in the step of forming the diffusion preventing film, the diffusion preventing film goes along an inner wall of the via hole in addition to an inside of the recess groove, and
wherein in the step of depositing the conductive metal which is to be the material of the embedded interconnection, the conductive metal which is to be the material of the embedded interconnection fills in the recess groove and the via hole which are covered with the diffusion preventing film.

8. The manufacturing method for a semiconductor device according to claim 7, further comprising the step of:
forming a lower interconnection traveling through a region corresponding to the specified region, and a lower etching stopper film which is made of a material selectively etchable with respect to the interlayer insulating film and which is in contact with an upper face of the lower interconnection, on the substrate in this order before the step of forming the interlayer insulating film,
wherein, following the forming of the via hole, the lower etching stopper film exposed in a bottom of the via hole is removed by etching.

9. (canceled)

10. (canceled)
